(19) United States
(12) Patent Application Publication
(10) Pub. No.: US 2003/0173607 A1
(43) Pub. Date: Sep. 18, 2003

(54) Semiconductor memory device

(76) Inventor: Tohru Takeshima, Kawasaki (JP)

Correspondence Address: ARENT FOX KINTNER PLOTKIN & KAHN, 1050 CONNECTICUT AVENUE, N.W., SUITE 400, WASHINGTON, DC, 20036, US

(21) Appl. No.: 10/336,043

(22) Filed: Jan. 3, 2003

(30) Foreign Application Priority Data
Mar. 8, 2002 (JP) 2002-063688

(51) Int. Cl. H01L 29/76; H01L 31/062

(52) U.S. Cl. 257/296; 257/202; 257/207; 257/208; 257/295

(57) ABSTRACT

A semiconductor memory device includes a memory cell which has a transistor and a ferroelectric capacitor, the transistor having a source-drain path and a gate connected to a word line, the capacitor being connected at a first end to a plate line and connected at a second end to a bit line through the source-drain path. A control circuit controls, during a test-mode operation, the memory cell so that a plate-line signal sent through the plate line to the memory cell and a bit-line signal sent through the bit line to the memory cell are set at a same potential.

### CROSS-REFERENCE TO RELATED APPLICATIONS

This application is based upon and claims the benefit of priority from the prior Japanese Patent Application No. 2002-063688, filed on Mar. 8, 2002, the entire contents of which are hereby incorporated by reference.

### BACKGROUND OF THE INVENTION

1. Field of The Invention

The present invention generally relates to a semiconductor memory device, and more particularly to a semiconductor memory device which uses a ferroelectric capacitor as a memory element.

2. Description of the Related Art

A ferroelectric capacitor is used as a nonvolatile memory element, and it has the characteristics that enable the reading and writing of data at high speed. A semiconductor memory device using the ferroelectric capacitor as a memory element (which is, hereinafter, called a ferroelectric memory) is put in practical use by utilizing such characteristics.

FIG. 1 shows a memory cell 1 in a conventional semiconductor memory device. The memory cell 1 includes a ferroelectric capacitor 12 as a memory element.

As shown in FIG. 1, the memory cell 1 is a unit circuit which stores 1-bit information in the conventional ferroelectric memory. The ferroelectric capacitor 12 is connected at one end to the plate line (PL) 18 and connected at the other end to the transfer transistor 10. The transistor 10 has a source-drain path and a gate. The gate of the transistor 10 is connected to the word line (WL) 14. The end of the ferroelectric capacitor 12 is connected to the bit line (BL) 16 through the source-drain path of the transistor 10. The bit line 16 is one of the pair of the complementary bit lines related to the memory cell 1 in the conventional semiconductor memory device.

A description will now be given of operation of the ferroelectric capacitor 12. FIG. 3 shows the hysteresis characteristic of the ferroelectric capacitor 12 of the memory cell of FIG. 1.

By applying positive potential to one electrode 12a of the ferroelectric capacitor 12 to the other electrode 12b of the capacitor 12, the electric field is increased to the value of the point A in the characteristic of FIG. 3, and the polarization P1 occurs.

Next, if the electric field is reset to 0, the polarization is not reset to 0 but the remnance, which is indicated by P0 in the characteristic of FIG. 3, is produced.

Next, if the electric field in the reverse direction is applied to the capacitor 12 to the value of the point B, the polarization is reset 0.

Furthermore, if the electric field in the reverse direction is continuously applied to the value of the point C, the polarization P2 in the reverse direction occurs.

Next, if the electric field is reset to 0, the remnance, which is indicated by P3 in FIG. 3 and opposite to the remnance P0 with respect to the origin, is produced.

Next, if the electric field applied to the capacitor 12 is increased to the value of the point D, the polarization is reset to 0. The strength of the electric field applied corresponding to the values of the points B and D is called the coercive force.

Furthermore, if the electric field is again applied to the value of the point A, the polarization P1 is produced again.

Therefore, the ferroelectric capacitor 12 has two remnance states P0 and P3 when the electric field applied to the capacitor 12 is reset to 0.

The above-mentioned hysteresis characteristics of the ferroelectric capacitor 12 are derived from the change of the relative positions of the atoms constituting the ferroelectric material crystal, and each remnance state of the ferroelectric capacitor 12 does not change in time, unless the electric field is applied. Accordingly, it becomes possible using such characteristics of the ferroelectric capacitor to constitute the nonvolatile semiconductor memory device.

FIG. 2 is a waveform diagram of control signals which are inputted to the word line and the plate line during a normal operation of the memory cell 1 of FIG. 1.

In FIG. 2, c(WL) indicates the waveform of a word-line signal which is inputted into the word line (WL) 14, a(PL) indicates the waveform of a plate-line signal which is inputted into the plate line (PL) 18, and the arrow “ta” indicates the time at which the sense amplifier coupled to the bit line is activated or turned ON.

As shown in FIG. 2, at the time t0, both the plate-line signal “a” inputted to the plate line 18 and the word-line signal “c” inputted to the word line 14 are at the low (L) level. Moreover, at the time t0, the bit line 16 is precharged to the low (L) level. Suppose that the ferroelectric capacitor 12 at this time is in the condition of the polarization P3 shown in FIG. 3.

Next, at a certain time after the bit line 16 is set in a floating state, a rising edge of the word-line signal “c” occurs and it is set to the high (H) level. In response to this, the plate line signal “a” is set to the high (H) level. At the time t1, the polarization P1 shown in FIG. 3 is created in the ferroelectric capacitor 12.

Next, the sense amplifier coupled to the bit line 16 is turned ON at the time indicated by the arrow “ta”. For example, the data is read out from the memory cell 1 at the time t2. Thereby, the bit line 16 is set to the high (H) level. At this time, the ferroelectric capacitor 12 is in the condition of the remnance P0 shown in FIG. 3.

Next, a falling edge of the plate-line signal “a” occurs and it is set to the low (L) level. In the ferroelectric capacitor 12, the polarization P2 shown in FIG. 3 is created at the time t3. Next, the sense amplifier is turned OFF, and the bit line 16 is precharged to the low (L) level. At the time t4, the ferroelectric capacitor 12 is in the condition of the remnance P3 shown in FIG. 3.

As described above, the control signals inputted to the word line, the plate line, and the bit line of the memory cell 1 are controlled, and the data read-out operation of the memory cell 1 of FIG. 1 is carried out.

However, when a stress test operation of the memory cell 1 is performed in a manner similar to the normal operation shown in FIG. 2, stress may be applied to the ferroelectric capacitor 12, which will cause the degradation of the memory cell 1. For example, in a case of reading of the data from the memory cell 1, the following problem may arise if the stress test is performed to the conventional ferroelectric memory. At the time of transition from the time t4 to the time t1, and at the time of transition from the time t2 to the time t3, the direction of the charge applied to the ferroelectric capacitor 12 is reversed, and this serves as the stress to the ferroelectric capacitor 12, which will cause the degradation of the memory cell 1.

Generally, in the case of the ferroelectric memory, the number of times of accessing the memory is limited due to the characteristics of the ferroelectric capacitor. If the stress test or the like is performed to the ferroelectric memory, the stress will be frequently applied to the ferroelectric capacitor, and the life of the memory element will be shortened.

For this reason, in order to perform the stress test of the conventional ferroelectric memory, it has been necessary to expect that a certain amount of degradation of the ferroelectric capacitor of the memory cell is unavoidable. It has been necessary that the stress test of the conventional ferroelectric memory is performed while a certain amount of degradation of the ferroelectric capacitor is taken into consideration in advance.

Or, when importance is given to the prevention of degradation of the ferroelectric capacitor as much as possible, it is difficult to ensure that the stress is not applied to a specific portion of the ferroelectric memory during the stress test operation of the memory cell.

In order to solve the above-described problems, there is the demand for a semiconductor memory device which is configured to ensure that only the ferroelectric capacitor is not stressed while the other elements of the memory cell are activated or stressed during a stress test operation even when the word line 14 is selected and the transfer transistor 10 of the memory cell 1 is turned ON similar to the normal operation shown in FIG. 2.

### SUMMARY OF THE INVENTION

An object of the present invention is to provide an improved semiconductor memory device in which the above-described problems are eliminated.

Another object of the present invention is to provide a semiconductor memory device which has a circuit configuration that controls, during a stress test, the signals sent through the word line, the plate line and the bit line to the memory cell, so that only the ferroelectric capacitor is not stressed while the other elements of the memory cell are activated or stressed for monitoring the quality of the memory cell array under the stress test.

The above-mentioned objects of the present invention are achieved by a semiconductor memory device which comprises: a memory cell which has a transistor and a ferroelectric capacitor, the transistor having a source-drain path and a gate connected to a word line, the capacitor being connected at a first end to a plate line and connected at a second end to a bit line through the source-drain path; and a control circuit which controls, during a test-mode operation, the memory cell so that a plate-line signal sent through the plate line to the memory cell and a bit-line signal sent through the bit line to the memory cell are set at a same potential.

The above-mentioned objects of the present invention are achieved by a semiconductor memory device which comprises: a memory cell which has a transistor and a ferroelectric capacitor, the transistor having a source-drain path and a gate connected to a word line, the capacitor being connected at a first end to a plate line and connected at a second end to a bit line through the source-drain path; and a signal selection circuit which outputs, during a test-mode operation, a control signal to the word line of the memory cell, the control signal having a potential that is produced based on a plate-line signal sent through the plate line to the memory cell.

The above-mentioned objects of the present invention are achieved by a semiconductor memory device which comprises: a memory cell which has a transistor and a ferroelectric capacitor, the transistor having a source-drain path and a gate connected to a word line, the capacitor being connected at a first end to a plate line and connected at a second end to a bit line through the source-drain path; and a signal selection circuit which sets, during a test-mode operation, the plate line of the memory cell in a floating state so that the capacitor connected at the first end to the plate line is disconnected from a plate-line driver.

The above-mentioned objects of the present invention are achieved by a semiconductor memory device which comprises: a memory cell which has a transistor and a ferroelectric capacitor, the transistor having a source-drain path and a gate connected to a word line, the capacitor being connected at a first end to a plate line and connected at a second end to a bit line through the source-drain path; and a control circuit which sets, during a test-mode operation, the bit line of the memory cell in a floating state so that the capacitor connected at the second end to the bit line is disconnected from a column switch.

According to the semiconductor memory device of the present invention, when the stress test is performed to individual memory cells of the memory cell array, it is possible to prevent the ferroelectric capacitor from being stressed and examine the quality of the other elements of the memory cell. Therefore, the semiconductor memory device of the present invention is effective in performing the screening test of semiconductor memory devices without shortening the operational life of the ferroelectric capacitors.

### BRIEF DESCRIPTION OF THE DRAWINGS

Other objects, features and advantages of the present invention will become apparent from the following detailed description when read in conjunction with the accompanying drawings.

FIG. 1 is a diagram of a memory cell in a conventional semiconductor memory device.

FIG. 2 is a waveform diagram of select signals which are inputted to the word line and the plate line during a normal operation of the memory cell of FIG. 1.

FIG. 3 is a diagram for explaining the hysteresis characteristic of a ferroelectric capacitor of the memory cell of FIG. 1.

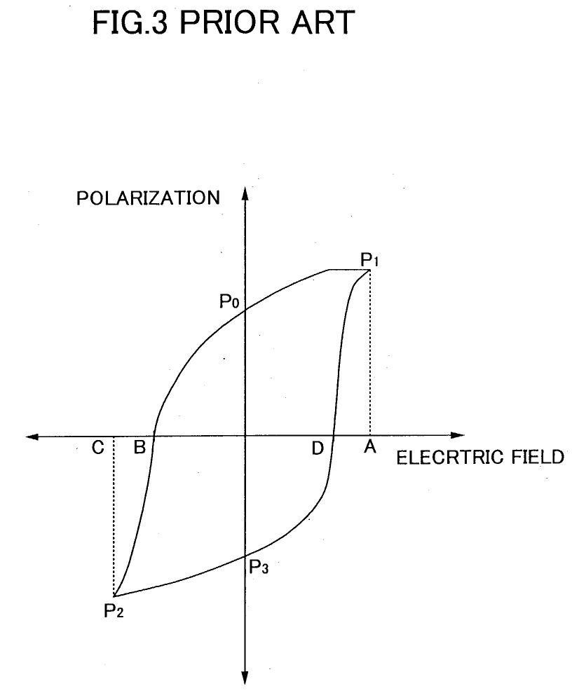

FIG. 4 is a block diagram of a semiconductor memory device of the first preferred embodiment of the invention.

FIG. 5A and FIG. 5B are circuit diagrams of a plate-line control circuit in the semiconductor memory device shown in FIG. 4.

FIG. 6 is a block diagram of a semiconductor memory device of the second preferred embodiment of the invention.

FIG. 7 is a circuit diagram of a signal selection circuit of the memory cell in the semiconductor memory device of FIG. 6.

FIG. 8 is a block diagram of a semiconductor memory device of the third preferred embodiment of the invention.

FIG. 9 is a circuit diagram of a signal selection circuit in the semiconductor memory device of FIG. 8.

### DETAILED DESCRIPTION OF PREFERRED EMBODIMENTS

A description will now be given of preferred embodiments of the present invention with reference to the accompanying drawings.

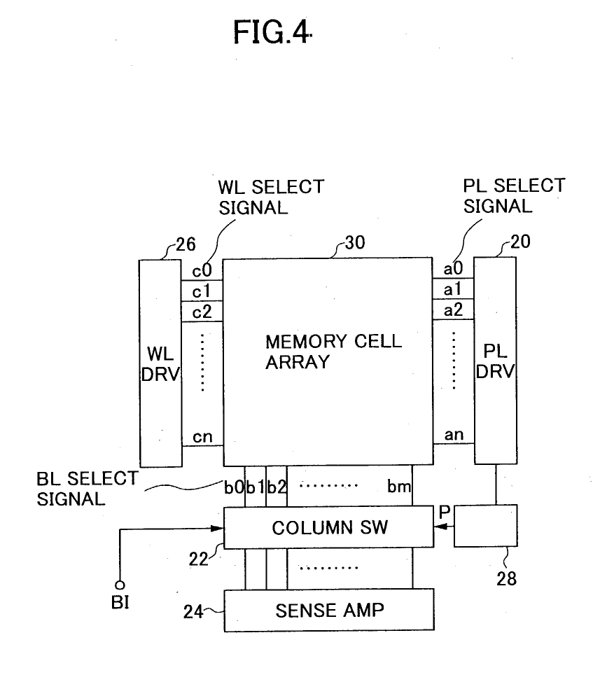

FIG. 4 shows a semiconductor memory device of the first preferred embodiment of the invention.

As shown in FIG. 4, the semiconductor memory device of the present embodiment includes a plate-line driver (PL DRV) 20, a column switch (SW) 22, a sense amplifier 24, a word-line driver (WL DRV) 26, a plate-line control circuit 28, and a memory cell array 30. The semiconductor memory device of FIG. 4 is the ferroelectric memory using the ferroelectric capacitor as a memory element.

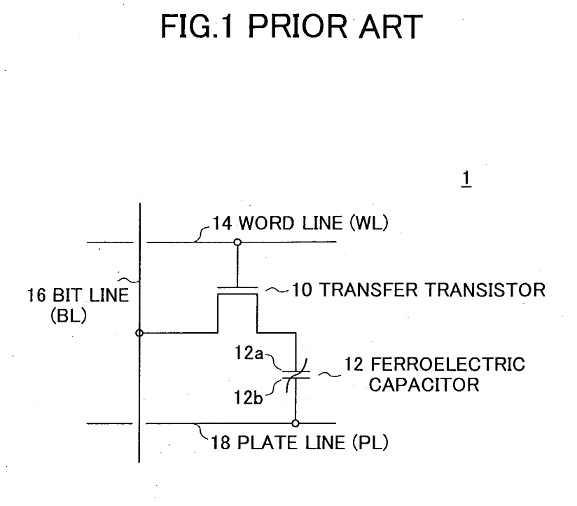

For the sake of convenience, it is assumed that the composition of the memory cell array 30 in the semiconductor memory device of FIG. 4 is essentially the same as the memory cell array as shown in FIG. 1, and a description thereof will be omitted. Namely, in the present embodiment, each memory cell of the memory cell array 30 includes the transfer transistor 10 and the ferroelectric capacitor 12 as showed in FIG. 1. The transistor 10 of each memory cell has a source-drain path and a gate connected to the word line (WL) 14. The capacitor 12 of each memory cell is connected at a first end to the plate line (PL) 18 and connected at a second end to the bit line (BL) 16 through the source-drain path of the transistor

For example, the transfer transistor 10 in the present embodiment is formed as a field-effect transistor (FET) on the semiconductor substrate. For example, the ferroelectric capacitor 12 in the present embodiment is formed with a pair of electrodes of a conductive material and a core member of a ferroelectric material interposed between the electrodes through a gap.

In the semiconductor memory device of FIG. 4, the memory cell array 30 is configured by arranging the individual memory cells in columns and rows in a 2-dimensional matrix formation. Each column of the memory cell array 30 includes the bit line BL which is connected to the ferroelectric capacitor 12 of the corresponding memory cell through the source-drain path of the transistor 10 of the corresponding memory cell. Each row of the memory cell array 30 includes the word line WL which is connected to the gate of the transistor 10 of the corresponding memory cell.

In the present embodiment, the plate line PL is separated from the word line WL and is made to extend in parallel to the word line WL. Moreover, the plate line PL of each row of the memory cell array-30 is connected to the electrode 12b of the ferroelectric capacitor 12 of the corresponding memory cell. The electrode 12a of the ferroelectric capacitor 12 is connected to the transistor 10, and the electrodes 12a and 12b are opposed to each other in the ferroelectric capacitor 12.

Moreover, in the semiconductor memory device of FIG. 4, the plate-line driver 20 is connected to the individual plate lines PL of the memory cell array 30, and outputs a plate-line select signal (a0, a1, . . . an) to the plate lines PL of the memory cell array 30. In accordance with the plate-line select signal sent by the plate-line driver 20, any of the plate lines PL of the memory cell array 30 which are respectively connected to the memory cells arrayed in the rows are selectively activated.

The column switch 22 generates a bit-line select signal (b0, b1, . . . bn) based on the memory-access control signal sent by a command decoder (not shown), and outputs the bit-line select signal to the bit lines BL of the memory cell array 30, which are connected to the memory cells that arrayed in the memory cell array 30 along any of the word lines WL selected by the word-line select signal (c0, c1, . . . cn).

Moreover, in the semiconductor memory device of FIG. 4, the sense amplifier 24 reads out respective data from the memory cells of the memory cell array 30. When the data is read out from the corresponding memory cells of the memory cell array 30 by the sense amplifier 24, the bit lines BL of the corresponding memory cells are selected by the column switch 22, and the word lines WL of the corresponding memory cells are selected by the word-line select signal. The word-line driver 26 generates a word-line select signal (c0, c1, . . . cn) based on the memory-access control signal sent by the command decoder (not shown), and outputs the word-line select signal to the word lines WL of the memory cell array 30.

In the present embodiment, the plate-line control circuit 28 is provided to control, during a test-mode operation, each memory cell of the memory cell array so that the plate-line signal sent through the plate line PL to the memory cell and the bit-line signal sent through the bit line BL to the memory cell are set at a same potential.

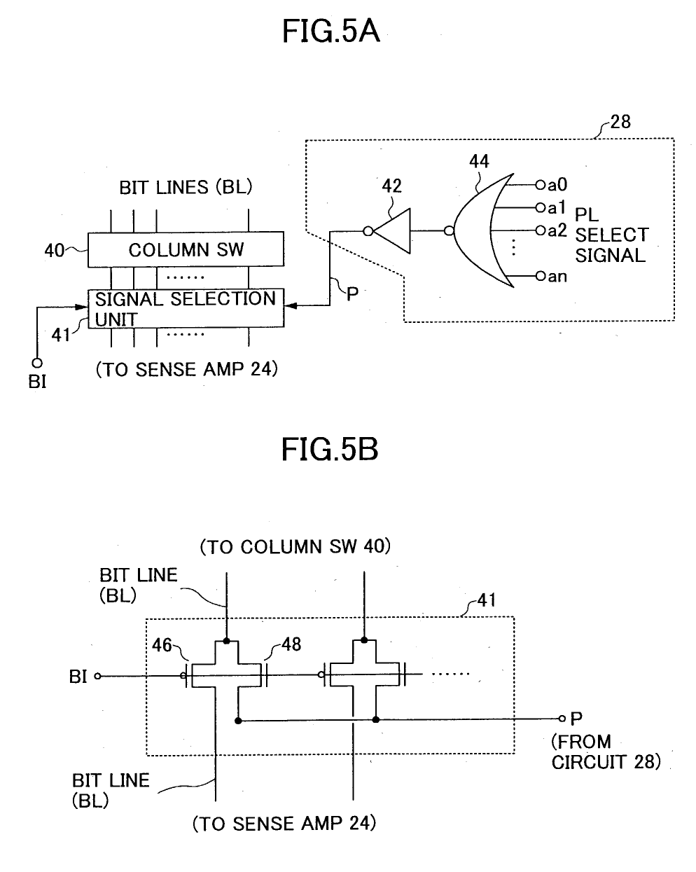

FIG. 5A shows an example of the plate-line control circuit 28 in the semiconductor memory device of FIG. 4.

The plate-line control circuit 28 of FIG. SA includes an inverter 42 and an NOR circuit 44. The NOR circuit 44 receives the plate-line select signal (a0, a1, . . . an) sent by the plate-line driver 20, and outputs the signal, which is produced by taking the NOR logic of the received plate-line select signal, to the input of the inverter 42.

The inverter 42 reverses the level of the received NOR logic signal and outputs a control signal P to the column switch 22 of FIG. 4 based on the reversed level of the received NOR logic signal.

Moreover, as shown in FIG. 5A, in the semiconductor memory device of the present embodiment, the column switch 22 includes a column switch portion 40 and a signal selection circuit 41. The column switch portion 40 has the circuit composition that is the same as the composition of the column switch of the known semiconductor memory device.

The signal selection circuit 41 of the column switch 22 receives at its input the test-mode signal BI sent by the external terminal or the control circuit (not shown). The signal selection circuit 41 receives at its input the signal P sent by the inverter 42 of the plate-line control circuit 28.

The test-mode signal BI is set to the low (L) level when the normal operation of the semiconductor memory device is requested, and it is set to the high (H) level when the stress-test-mode operation of the semiconductor memory device is requested.

FIG. 5B shows an example of the signal selection circuit 41 of FIG. 5A in the present embodiment.

As shown in FIG. 5B, in the signal selection circuit 41, a number of pairs of transistors 46 and 48 are connected in parallel for the respective bit lines of the column switch portion 40 (namely, the respective bit lines of the memory cell array 30). Each bit line of the column switch portion 40 is connected to one of the respective bit lines of the sense amplifier 24 through the source-drain path of the transistor 46 of one of the transistor pairs. The signal selection circuit 41 has an input terminal, which receives the test-mode signal BI sent by the external terminal or the control circuit (not shown). The input terminal is connected to both the gate (with the inverted input) of the transistor 46 of each transistor pair and the gate of the transistor 48 of each transistor pair. Moreover, the connection from the output of the inverter 42 of the plate-line control circuit 28 is connected to the source-drain path of the transistor 48 of each transistor pair in the signal selection circuit 41.

The signal selection circuit 41 of FIG. 5B is operated in accordance with the level of the test-mode signal BI.

That is, when the normal operation of the semiconductor memory device is requested (BI=L), the transistor 46 of each transistor pair is turned ON and the transistor 48 of each transistor pair is turned OFF. At this time (BI=L), the signal selection circuit 41 serves to connect each bit line (BL) of the memory cell array 30 to a corresponding one of the bit lines of the sense amplifier 24, and the data of the corresponding memory cell of the memory cell array 30 is read out to the sense amplifier 24.

On the other hand, when the stress-test-mode operation of the semiconductor memory device is requested (BI=H), the transistor 46 of each transistor pair is turned OFF and the transistor 48 of each transistor pair is turned ON. At this time (BI=H), the signal selection circuit 41 serves to isolate the memory cell array 30 from the sense amplifier 24. The signal selection circuit 41 delivers the signal P, which is received from the inverter 42 of the plate-line control circuit 28, to the bit line BL of each memory cell of the memory cell array 30 via the column switch portion 40. At this time, the plate line PL of corresponding memory cell of the memory cell array 30 is selected according to the plate-line select signal output by the plate-line driver 20. The output signal P of the plate-line control circuit 28 (which is the same as the signal sent through the plate line PL) is sent to all the bit lines BL of the memory cells which are arranged in the memory cell array 30 along the selected plate line PL.

Accordingly, during a test-mode operation, the plate-line control circuit 28 in the present embodiment controls each memory cell of the memory cell array 30 so that the plate-line signal sent through the plate line PL 18 to the memory cell and the bit-line signal sent through the bit line BL 16 to the memory cell are set at a same potential. Since the bit-line signal sent through the bit line BL 16 and the plate-line signal sent through the plate line PL 18 are the same signal, any voltage between the electrodes of the ferroelectric capacitor 12 is not applied. Hence, the polarization reversal of the ferroelectric capacitor 12 does not take place.

Moreover, in the semiconductor memory device of the preferred embodiment, if the plate line PL of a corresponding memory cell of the memory cell array 30 is selected according to the plate-line select signal. The output signal P of the plate-line control circuit 28 (which is the same as the signal sent through the plate line PL) is sent to all the bit lines BL of the memory cells which are arranged in the memory cell array 30 along the selected plate-line PL. Therefore, the time needed for performing the stress test for the semiconductor memory device can be shortened.

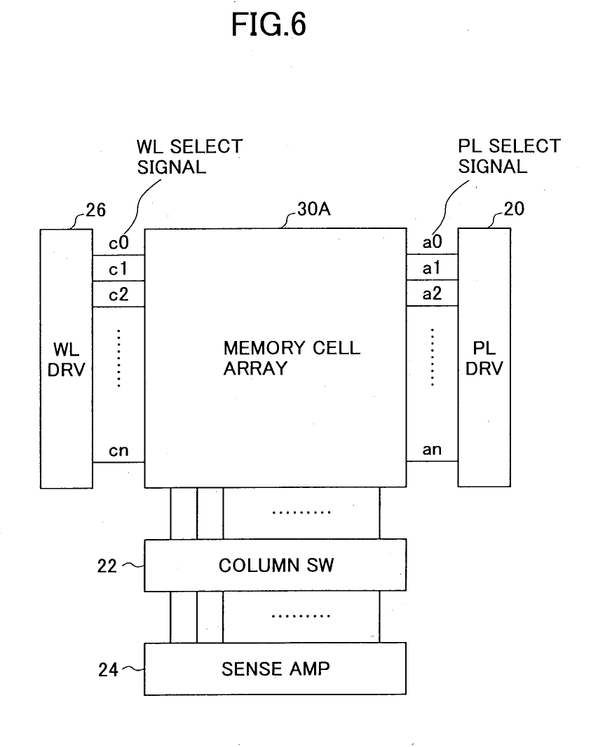

Next, FIG. 6 shows a semiconductor memory device of the second preferred embodiment of the invention.

The semiconductor memory device shown in FIG. 6 is a ferroelectric memory, which includes the plate-line driver 20, the column switch 22, the sense amplifier 24, the word-line driver 26, and the memory cell array 30A.

In the present embodiment, the composition of the plate-line driver 20, the column switch 22, the sense amplifier 24, and the word-line driver 26 is essentially the same as the composition of the previous embodiment of FIG. 4, and a description thereof will be omitted.

In the present embodiment, when the stress test is performed for each memory cell of the memory cell array 30A, a signal selection circuit (which will be described later) sends out a word-line signal, which is complementary to the plate-line signal inputted to the plate line (PL) 18 of the corresponding memory cell, to the word line (WL) 14 of the corresponding memory cell.

In the memory cell array of the conventional semiconductor memory device, when the transfer transistor 10 of the corresponding memory cell shown in FIG. 1 is turned ON, the voltage is applied between the ends 12a and 12b of the ferroelectric capacitor 12 due to the difference between the potential of the bit-line signal from the bit line (BL) 16 and the potential of the plate-line signal from the plate line (PL) 18.

In the memory cell array 30A of the present embodiment, when the signal inputted from the plate line (PL) 18 is at the high (H) level, it is configured so that the word line (WL) 14 of the memory cell is not selected, regardless of whether the word-line signal “c (WL)” from the word-line driver 26 is at the high (H) level or not.

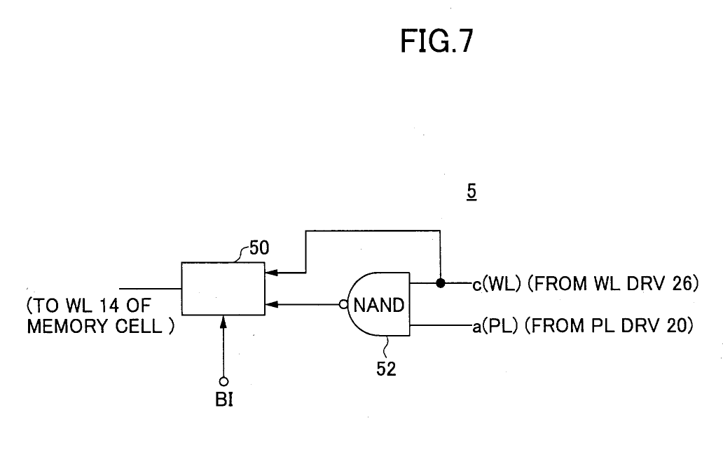

FIG. 7 shows an example of the signal selection portion 5 of the memory cell in the semiconductor memory device of FIG. 6.

In order to perform the above-described control, the signal selection portion 5 of FIG. 7 is arranged for each memory cell of the memory cell array 30A. Namely, in addition to the circuit configuration of the memory cell shown in FIG. 1, in the present embodiment, each memory cell of the memory cell array 30A includes the signal selection portion 5 of FIG. 7.

As shown in FIG. 7, the signal selection portion 5 includes a signal selection circuit 50 and an NAND circuit 52.

The NAND circuit 52 has a first input connected to one of the respective plate lines of the plate-line driver 20. A plate-line signal “a (PL)” from the corresponding one of the plate lines of the plate-line driver 20 is inputted to the first input of the NAND circuit 52.

The NAND circuit 52 has a second input connected to one of the respective word lines of the word-line driver 26. A word-line signal “c (WL)” from the corresponding one of the word lines of the word-line driver 26 is inputted to the second input of the NAND circuit 52.

Moreover, the signal selection circuit 50 of the present embodiment is configured so that it is similar to the signal selection circuit 41 of FIG. 5B. However, in the signal selection circuit 50 in FIG. 7, the connection of the bit lines in FIG. 5B is replaced by the connection of the word lines, and the connection from the output of the plate-line control circuit 28 in FIG. 5B is replaced by the connection from the output of the NAND circuit 52.

Namely, the signal selection circuit 50 of FIG. 7 receives at one input the word-line signal “c (WL)” from the word-line driver 26. The signal selection circuit 50 receives at its input the output signal of the NAND circuit 52 which is produced by taking the NAND logic of the word-line signal “c (WL)” and the plate-line signal “a (PL)”. Moreover, the signal selection circuit 50 receives at its input the test-mode signal BI which is sent from the external terminal or the control circuit (not shown).

The test-mode signal BI is set to the low (L) level when the normal operation of the semiconductor memory device is requested, and it is set to the high (H) level when the stress-test-mode operation of the semiconductor memory device is requested.

At the time of the normal operation (BI=L), the signal selection circuit 50 serves to pass the word-line signal c (WL), which is received from the word-line driver 26, to the word line WL of the memory cell array 30A in accordance with the test-mode signal BI.

At the time of the test mode operation (BI=H), the signal selection circuit 50 sends out the output signal of the NAND circuit 52, which is produced by taking the NAND logic, to the word line WL of the memory cell array 30A in accordance with the test-mode signal BI.

Therefore, in case the stress test is performed for the semiconductor memory device of the present embodiment (BI=H), if the signal sent to the plate line (PL) 18 of the corresponding memory cell of the memory cell array 30A is at the high (H) level, the signal sent to the word line (WL) 14 of that memory cell is set to the low (L) level, regardless of whether the word-line signal “c (WL)” from the word-line driver 26 is at the high (H) level or not.

Since the signal sent to the word line (WL) 14 is set to the low (L) level even if the word-line select signal c from the word-line driver 26 is at the high (H) level, the word line (WL) 14 of the corresponding memory cell is not selected. Hence, voltage is not applied between the electrodes of the ferroelectric capacitor 12, and the polarization reversal of the ferroelectric capacitor 12 does not take place.

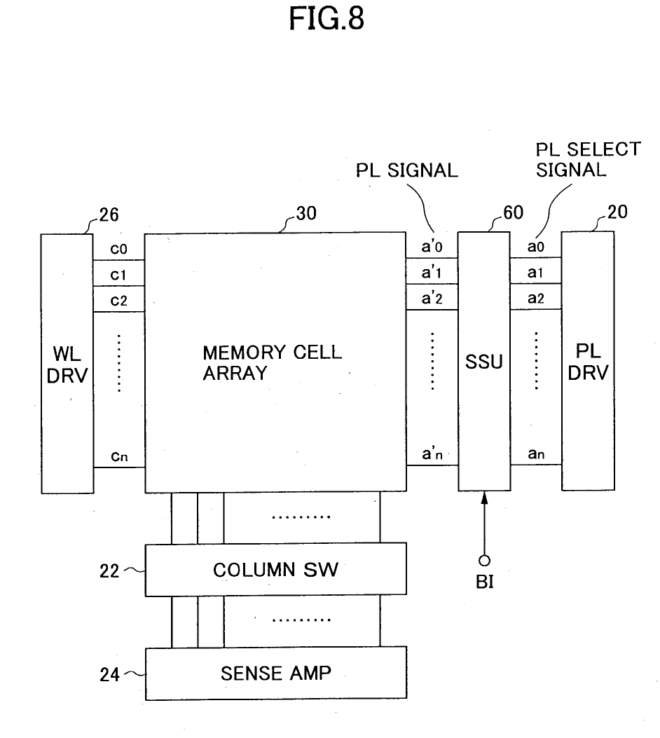

Next, FIG. 8 shows a semiconductor memory device of the third preferred embodiment of the invention.

The semiconductor memory device of FIG. 8 is a ferroelectric memory, which includes the plate-line driver 20, the column switch 22, the sense amplifier 24, the word-line driver 26, the memory cell array 30, and the signal selection circuit 60.

In the present embodiment, the composition of the plate-line driver 20, the column switch 22, the sense amplifier 24, the word-line driver 26, and the memory cell array 30 is essentially the same as the composition of the previous embodiment of FIG. 4, and a description thereof will be omitted.

In the present embodiment, when the stress test is performed for each memory cell of the memory cell array 30, the signal selection circuit 60 sets the plate line (PL) 18 connected to a corresponding one of the memory cells of the memory cell array 30 in a floating state so that the ferroelectric capacitor connected to the plate line 18 is disconnected from the plate-line driver 20.

The signal selection circuit 60 of FIG. 8 is connected at its inputs to the respective plate lines of the plate-line driver 20, and the respective plate lines which correspond to the outputs of the signal selection circuit 60 are connected to the plate lines PL of the memory cell array 30.

Moreover, the signal selection circuit 60 receives the test-mode signal BI sent out from the external terminal or the control circuit (not shown). The test-mode signal BI is set to the low (L) level when the normal operation of the semiconductor memory device is requested, and it is set to the high (H) level when the stress-test-mode operation of the semiconductor memory device is requested.

The signal selection circuit 60 makes the plate line PL of the memory cell array 30 pass the plate-line select signal (a0, a1, . . . an) received from the plate-line driver 20 as it is according to this test-mode signal BI at the time (BI=L) of the normal operation of the semiconductor memory device.

At the time (BI=H) of the stress test mode, the signal selection circuit 60 separates the plate-line select signal received from the plate-line driver 20 from the memory cell array 30, and sends out the plate line signal (a0′, a1′, . . . an′) of floating to the plate line PL of the memory cell array 30.

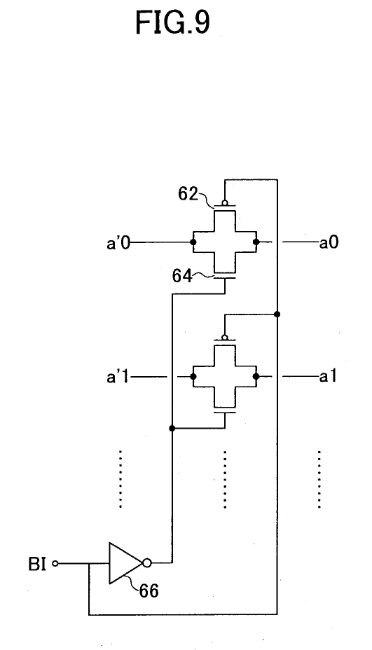

FIG. 9 shows an example of the signal selection circuit 60 in the semiconductor memory device of FIG. 8.

As shown in FIG. 9, in the signal selection circuit 60, the pair of CMOS transistors 62 and 64 are connected with respect to each of the respective plate lines of the plate-line driver 20. Such pairs of the transistors 62 and 64 are provided in the parallel configuration.

Each of the plate lines of the plate-line driver 20 is connected to one of the plate lines PL of the memory cell array 30 through the source-drain path of each transistor pair of the transistors 62 and 64.

The input terminal which receives the test-mode signal BI sent from the external terminal or the control circuit is connected to both the gate (the reversal input) of the transistor 62 of each transistor pair and the input terminal of the inverter 66. The output of the inverter 66 is connected to the gate of the transistor 64 of each transistor pair.

As described above, the signal selection circuit 60 of this preferred embodiment performs the test-mode operation in response to the test-mode signal BI. Namely, both the transistors 62 and 64 of each transistor pair are turned ON at the time (BI=L) of the normal operation of the semiconductor memory device, and the plate-line select signal (a0, a1, . . . an) received from the plate-line driver 20 is passed to the plate lines PL of the memory cell array 30 through the signal selection circuit 60.

On the other hand, both the transistors 62 and 64 of each transistor pair are turned OFF at the time (BI=H) of the stress test mode operation, the plate-line select signal received from the plate-line driver 20 is isolated from the memory cell array 30 by the signal selection circuit 60, and the plate-line signal (a0′, a1′, . . . an′) of a floating state is sent out to the plate lines PL of the memory cell array 30.

Accordingly, during a stress-test-mode operation (BI=H), the plate-line signal, which is sent to the plate line (PL) 18 of a corresponding memory cell of the memory cell array 30, is set in a floating state, and any voltage between the electrodes of the ferroelectric capacitor 12 is not applied. Hence, the polarization reversal of the ferroelectric capacitor 12 does not take place.

Next, a description will be given of a semiconductor memory device of a further preferred embodiment of the invention with reference to FIG. 8 and FIG. 9.

In the present embodiment, during a stress-test-mode operation of each of the memory cells of the semiconductor memory device, the control circuit (which is similar to the signal selection circuit 60 in FIG. 8) sets the bit line 16 of the memory cell in a floating state so that the ferroelectric capacitor 12 connected to the bit line 16 is disconnected from the column switch 22. The bit line 16 is not connected to the sense amplifier that is tuned ON.

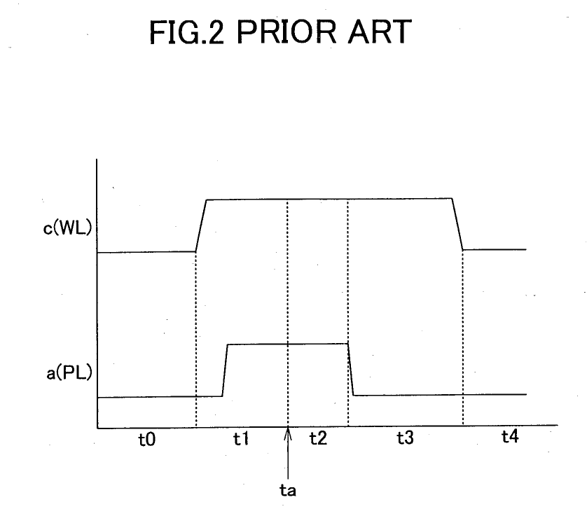

In the present embodiment, at the time t1 in FIG. 2, the polarization reversal of the ferroelectric capacitor 12 takes place. However, in the present embodiment, the bit line 16 of the memory cell is set in a floating state. The voltage applied to the capacitor 12 is reduced according to the ratio of the bit line capacity to the ferroelectric material capacity. In the semiconductor memory device of the present embodiment, the amount of polarization reversal in the ferroelectric capacitor 12 is adequately reduced.

According to the semiconductor memory device of the preferred embodiment mentioned above, when the stress test is performed to each memory cell of the memory cell array 30, it is possible to prevent the polarization reversal of the ferroelectric capacitor 12 from occurring. The sense amplifier is not turned ON and the bit line is set in a floating state.

As described in the foregoing, when the stress test is performed, the semiconductor memory device of the present invention can be tested without applying stress to the ferroelectric capacitor. Therefore, the screening test can be carried out to the semiconductor memory device of the present invention without shortening the life of the ferroelectric capacitor.

The present invention is not limited to the above-described embodiments, and variations and modifications may be made without departing from the scope of the present invention.

Further, the present invention is based on Japanese priority application No. 2002-063688, filed on Mar. 8, 2002, the entire contents of which are hereby incorporated by reference.

What is claimed is:

1. A semiconductor memory device comprising:
a memory cell having a transistor and a ferroelectric capacitor, the transistor having a source-drain path and a gate connected to a word line, the capacitor being connected at a first end to a plate line and connected at a second end to a bit line through the source-drain path; and
a control circuit controlling, during a test-mode operation, the memory cell so that a plate-line signal sent through the plate line to the memory cell and a bit-line signal sent through the bit line to the memory cell are set at a same potential.

2. The semiconductor memory device of claim 1, wherein, when a test-mode signal is received, the control circuit delivers a control signal, which is produced based on a plate-line select signal sent from a plate-line driver to the memory cell, to the bit line of the memory cell.

3. A semiconductor memory device comprising:
a memory cell having a transistor and a ferroelectric capacitor, the transistor having a source-drain path and a gate connected to a word line, the capacitor being connected at a first end to a plate line and connected at a second end to a bit line through the source-drain path; and
a signal selection circuit outputting, during a test-mode operation, a control signal to the word line of the memory cell, the control signal having a potential that is produced based on a plate-line signal sent through the plate line to the memory cell.

4. The semiconductor memory device of claim 3, wherein, when a test-mode signal is received, the signal selection circuit generates a potential of the control signal, which is output to the word line, by taking an NAND logic between a plate-line select signal sent from a plate-line driver to the memory cell and a word-line select signal sent from a word-line driver to the memory cell.

5. A semiconductor memory device comprising:
a memory cell having a transistor and a ferroelectric capacitor, the transistor having a source-drain path and a gate connected to a word line, the capacitor being connected at a first end to a plate line and connected at a second end to a bit line through the source-drain path; and
a signal selection circuit setting, during a test-mode operation, the plate line of the memory cell in a floating state so that the capacitor connected at the first end to the plate line is disconnected from a plate-line driver.

6. The semiconductor memory device of claim 5, wherein, when a test-mode signal is received, the signal selection circuit serves to cut off conduction between the plate line of the memory cell and a signal line of the plate-line driver.

7. A semiconductor memory device comprising:
a memory cell having a transistor and a ferroelectric capacitor, the transistor having a source-drain path and a gate connected to a word line, the capacitor being connected at a first end to a plate line and connected at a second end to a bit line through the source-drain path; and
a control circuit setting, during a test-mode operation, the bit line of the memory cell in a floating state so that the capacitor connected at the second end to the bit line is disconnected from a column switch.

8. The semiconductor memory device of claim 7, wherein, when a test-mode signal is received, the control circuit serves to cut off conduction between the bit line of the memory cell and a signal line of the column switch.
